(19) United States
(12) Patent Application Publication
(10) Pub. No.: US 2024/0332353 A1
(43) Pub. Date: Oct. 3, 2024

(54) METHODS OF FORMING DIE STRUCTURES WITH SCALLOPED SIDEWALLS AND STRUCTURES FORMED THEREBY

(71) Applicant: Intel Corporation, Santa Clara, CA (US)

(72) Inventors: Xavier F. Brun, Hillsboro, OR (US); Rajesh Surapaneni, Portland, OR (US); Brad S. Hamlin, Portland, OR (US)

(73) Assignee: Intel Corporation, Santa Clara, CA (US)

(21) Appl. No.: 18/129,737

(22) Filed: Mar. 31, 2023

(51) Int. Cl. H01L 29/06; H01L 21/78

(52) U.S. Cl. CPC H01L 29/0657; H01L 21/78

(57) ABSTRACT

Microelectronic integrated circuit package structures include a die having a dielectric die edge sidewall and a bulk silicon die edge sidewall, where the bulk silicon die edge sidewall is in substantial alignment with the dielectric die edge sidewall. The bulk silicon die edge sidewall has a plurality of scallop structures along a vertical distance of the bulk silicon die edge sidewall.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

As demand for high performance computing (HPC) continues to rise, integration of heterogeneous devices within an IC package has become an important performance driver. Wafer to wafer and die to wafer hybrid bonding requires an extremely flat and clean die bonding surface, such that surface roughness is desired to be less than about 1 nm. To achieve this clean bonding surface, currently backside (BS) plasma dicing (PD) is employed for die singulation, a time intensive and costly manufacturing process.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A-1E are cross-sectional views of IC package structures comprising die structures having scallop structures on bulk silicon die edge sidewalls, in accordance with some embodiments.

FIGS. 2A-2M illustrate cross-sectional views of structures formed during the fabrication of IC die structures comprising scallop structures on bulk silicon die edge sidewalls, in accordance with some embodiments.

FIG. 3 illustrates a flow chart of a process for the fabrication of IC package structures having die structures having scallop structures on bulk silicon die edge sidewalls, in accordance with some embodiments.

FIG. 4 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. In other embodiments, the term bond pad may refer to two or more bond pads which may bond to each other using a hybrid bond interface. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with packaging architectures and methods employing wafer to wafer and die to wafer hybrid bonding for heterogeneous integration. Such methods, including singulation of die to produce clean and flat surfaces for such hybrid bonding, are described herein. Challenges associated with producing flat, clean surfaces for hybrid die bonding include the degree of scribe lane alignment accuracy achieved during a dicing operation. Current backside dicing processes frequently produce defects such as notching (i.e., lateral etching of silicon into the sidewall of a die). Such notching defects can negatively affect device performance and yield of devices in an active area of a die/device, as well as decreasing throughput. The incorporation of a partial front side plasma dicing (PD) process may be employed subsequent to a dielectric etch process, which may then be followed by a die backside grinding process. Placement accuracy of the PD scribe lanes is improved by utilizing a front side PD process, as described in the embodiments herein.

Embodiments describe front side PD methods and structures formed thereby which provide clean, flat die surfaces with which to perform hybrid bonding processing. A reduction in the number of lithographic and grinding operations is realized and die backside grinding is enabled. Further advantages of the embodiments presented herein include the enabling of partial singulation which reduces defects such as notching and improves the PD tool run rate.

Die and package structures fabricated according to the assembly processes of the embodiments herein may include an IC package where a die is coupled to a substrate, such as a package substrate. The die may comprise a processor die or a memory component, for example, or any other suitable microelectronic components. In an embodiment, the die may have a dielectric portion with a die edge sidewall. The dielectric die edge sidewall comprises a sidewall profile with a substantially continuous sidewall slope.

A bulk silicon portion of the die is on the dielectric portion, and comprises a bulk silicon die edge sidewall. The bulk silicon die edge sidewall is in substantial alignment with the dielectric die edge sidewall. The bulk silicon die edge sidewall has a sidewall profile comprising a plurality of scallop structures along a vertical distance of the bulk silicon die edge sidewall. In an embodiment, an interface region between the dielectric die edge sidewall and the bulk silicon die edge sidewall comprises a substantially vertical interface sidewall. The interface region is free of any concave notching structures. By forming the die structures having an interface region that is free of notching, partial PD is enabled, misalignment of scribe lines is avoided and thus the reliability and performance of devices incorporating the embodiments included herein is greatly enhanced.

The architecture described herein may be assembled and/or fabricated with one or more of the features or attributes provided in accordance with various embodiments. A number of different assembly and/or fabrication methods may be practiced generating die structures having a scalloped bulk die edge sidewall profile in substantially vertical alignment with a dielectric die edge sidewall portion and an interface region that is free of a concave notch in the silicon sidewall, according to one or more of the features or attributes described herein.

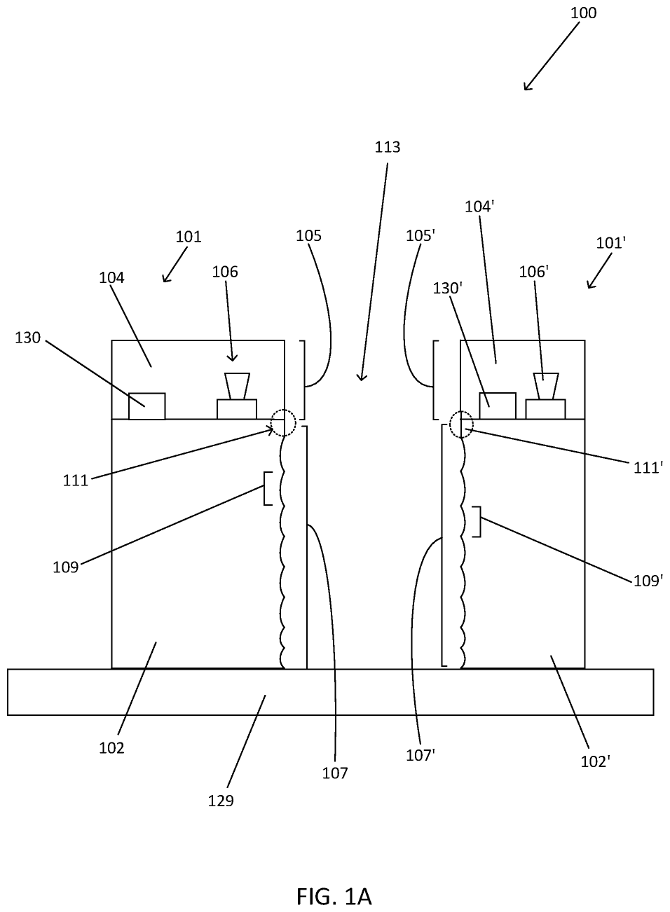

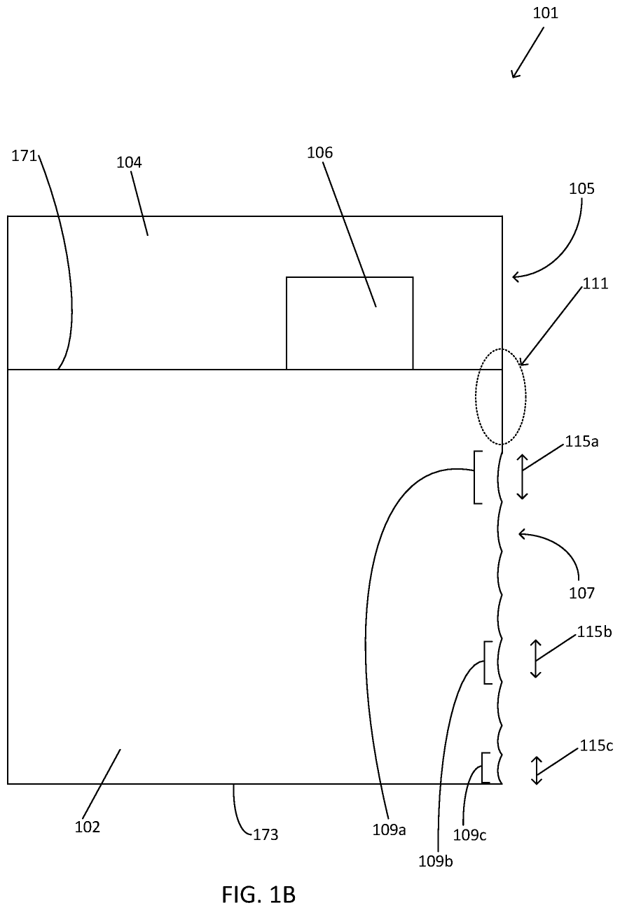

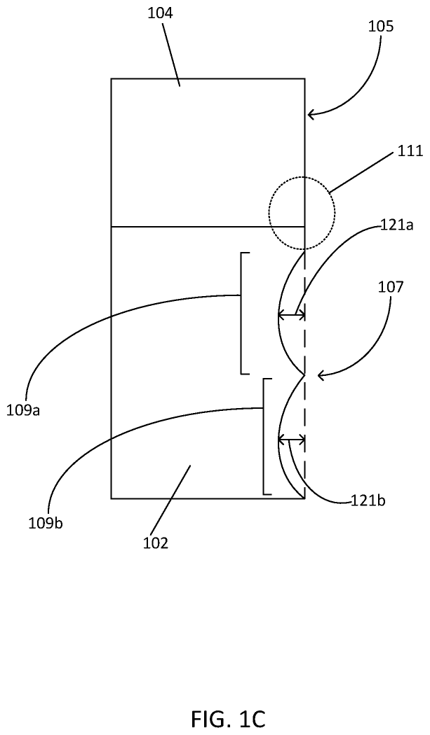

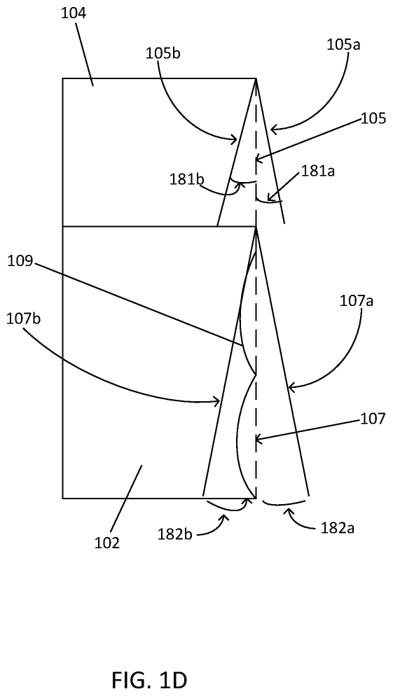

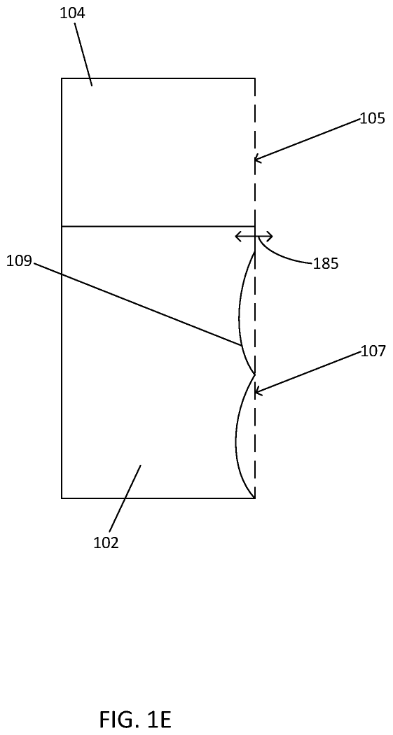

FIGS. 1A-1D illustrate embodiments of package structures including die structures. The die structures are formed utilizing front side partial dicing techniques using etch process thus enabling a reduction in processing operations. For example, the methods of fabrication described herein reduce the number of lithographic and grinding operations to produce the die structures of the embodiments.

FIG. 1A is a cross-sectional view of a portion of integrated circuit (IC) package structure 100, in accordance with some embodiments. In the embodiment depicted in FIGS. 1A, IC package structure 100 depicts a cross-sectional view of a portion of IC die structures according to some embodiments. As shown, a first die 101 and a second die 101′ are on a substrate 129. The first die 101 may comprise a dielectric portion 104 on a bulk silicon portion 102. The dielectric portion 104 may comprise any suitable dielectric materials, such as silicon nitride and or silicon dioxide materials, or any other suitable dielectric materials. The dielectric portion 104 may comprise metal layers/structures 106 within the dielectric portion 104. The second die 101′ may likewise comprise a dielectric portion 104′ on a bulk silicon portion 102′ and metal layer/structures 106. In an embodiment, the metal structures 106 may comprise portions of active or passive devices. In other embodiments, metal structures 106 may extend/be on a top surface of the dielectric portion 104 and may comprise a bond pad which may be hybrid bonded to an additional die (not shown).

The dielectric portions 104, 104′ comprise dielectric die edge sidewalls 105, 105′, respectively, having a sidewall profile comprising a substantially continuous sidewall slope. Although the dielectric die edge sidewalls 105, 105′ are depicted as having a substantially vertical profile, in some embodiments the dielectric die edge sidewalls 105, 105′ may comprise a sloped sidewall profile, and in some embodiments may comprise a profile that is slightly “V” shaped.

The dielectric portion 104 may comprise any number of devices 130, such as active and/or passive devices. For example, the dielectric portion 104 may comprise transistor devices and/or resistor structures within the dielectric portion 104. In an embodiment, the bulk silicon portions 102, 102′ of the first and second dies 101, 101′ may comprise silicon and/or silicon alloys. The first and second dies 101, 101′ may comprise IC dies and may comprise any suitable die/device in an embodiment.

In an embodiment, the first and second dies 101, 101′ the bulk silicon portions 102, 102′ are underlying the dielectric portions 101, 101′. The bulk silicon portions 102, 102′ comprise bulk silicon die edge sidewalls 107, 107′. The bulk silicon die edge sidewalls 107, 107′ are in substantial alignment with the dielectric die edge sidewalls 105, 105′. In some embodiments, a profile of the dielectric die edge sidewalls 105, 105′, may be inclined/angled during a dielectric etch, for example. In an embodiment, the dielectric die edge sidewall may comprise between about 0 degrees to about 20 degrees of a vertical profile. In an embodiment, a profile of the bulk silicon die edge sidewalls 107, 107′ may be substantially vertical, or in other embodiments may comprise between about 0 degrees to about 20 degrees of a vertical profile. In other embodiments the profile of the bulk silicon die edge sidewalls 107, 107′ may be optimized to produce a substantially vertical or in some cases a reentrant or angled profile, according to the particular design requirements.

An interface region 111 is a location at or near where the bulk silicon die edge sidewalls 107, 107′ and the dielectric die edge sidewalls 105, 105′ meet. For example, an interface region may be near an interface of the bulk silicon die edge sidewalls 107, 107′ and the dielectric die edge sidewalls 105, 105′. In an embodiment, the interface region 111 may comprise portions of the dielectric die edge sidewalls 105, 105′ and portions of DSE5F4Ethe bulk silicon die edge sidewalls 107, 107′, respectively wherein those portions are in vertical alignment and free of concave notch structures.

The bulk silicon die edge sidewalls 107, 107′ comprise sidewall profiles having a plurality of scalloped regions 109, 109′ along a vertical distance of the bulk silicon die edge sidewalls 107, 107′. In an embodiment, the bulk silicon die edge sidewall comprises four concave regions along a vertical distance of the bulk silicon die edge sidewall. In an embodiment, individual scallop structures 109, 109′ comprise a lateral width of between about 0.2 microns to about 5 microns. In an embodiment, an opening 113 may be between the first and second dies 101, 101′. The opening 113 may comprise a singulation opening, in an embodiment. The first and second dies 101, 101′ may be on a substrate 129. In an embodiment, the substrate 129 may comprise a carrier such as a glass carrier or may comprise a package substrate.

First and second dies 101, 101′ may comprise any suitable die/device including, but not limited to, a microprocessor, a chipset, a graphics device, a wireless device, a memory device, an application specific integrated circuit, a transceiver device, an input/output device, stacks thereof, or the like. In an embodiment, the dielectric portions 104, 104′ comprise one or more transistors/devices 130, wherein the one or more transistors 130 are over the bulk silicon portion 102 and are adjacent to the plurality of concave notches 109.

FIG. 1B is a cross-sectional view of an IC die structure 101, in accordance with some embodiments. IC die structure 101 includes an interface region 111 between dielectric die edge sidewall 105 and bulk silicon die edge sidewall 107. In an embodiment, the interface region 111 is free of the scallop structures 109. In other embodiments, the interface region 111 may comprise the scallop structure 109. In an embodiment, the bulk silicon portion 102 of the die 101 beneath the metal structure 106 is free of any notching i.e., has little to no lateral scalloping underneath the metal structure 106. The scallop structures 109 comprise a length 115 which decreases in a vertical direction from a first surface 171 to a second surface 173 of the bulk silicon portion 102. In other examples, the length 115 may be substantially the same according to design requirements. For example, the scallop structure 109a comprises a length 115a which is greater than a length 115b of the scallop structure 109b, and wherein the length 109b is greater than the length 109c of the scallop structure 109c.

In an embodiment, the scallop structures 109 comprise a lateral width 121 along the bulk silicon die edge sidewall 107 of the bulk silicon region 102 (FIG. 1C). The dielectric die edge sidewall 105 of the dielectric region 104 is free of the scallop structures 109, as is the interface region 111. In an embodiment, the lateral widths 121a, 121b of the scallop structures 109a, 109b respectively comprise about 0.2 microns to about 5 microns. In an embodiment, the lateral width 121a may be greater than the lateral width of 121b.

FIG. 1D depicts a depicts a cross-sectional view of a portion of IC die structures according to some embodiments. As shown, the dielectric die edge sidewall 105 of the dielectric portion 104 may be optimized to be between an angle (relative to a vertical profile as shown for the dielectric die edge sidewall 105) of about 0 to about 20 degrees, in an embodiment. For example, the dielectric die edge sidewall 105a may comprise an angle 181a relative to a vertical profile or the dielectric die edge sidewall 105b may comprise angle 181b relative to a vertical profile. In an embodiment, the angle 181a may comprise between about 4 degrees to about 10 degrees, but may comprise any angle 181a that is advantageous for the particular design requirements. Likewise, dielectric die edge sidewall 105b may comprise an angle 181b between about 4 degrees to about 10 degrees but may comprise any angle 181b that is advantageous for the particular design requirements.

In an embodiment, the bulk silicon die edge sidewall 107 of the bulk silicon portion 102 may be optimized to be between an angle (relative to a vertical profile as shown for the bulk silicon die edge sidewall 107) of about 0 to about 20 degrees, in an embodiment. For example, the bulk silicon die edge sidewall 107a may comprise an angle 182a relative to a vertical profile or the bulk silicon die edge sidewall 107b may comprise angle 182b relative to a vertical profile. In an embodiment, the angles 182a, 182b may comprise between about 4 degrees to about 10 degrees, but may comprise any angle 182a, 182b that is advantageous for the particular design requirements. In an embodiment, a lateral offset 185 between the dielectric die edge sidewall 105 and the bulk silicon die edge sidewall 107 is less than about 2 percent of the vertical profile (FIG. 1E).

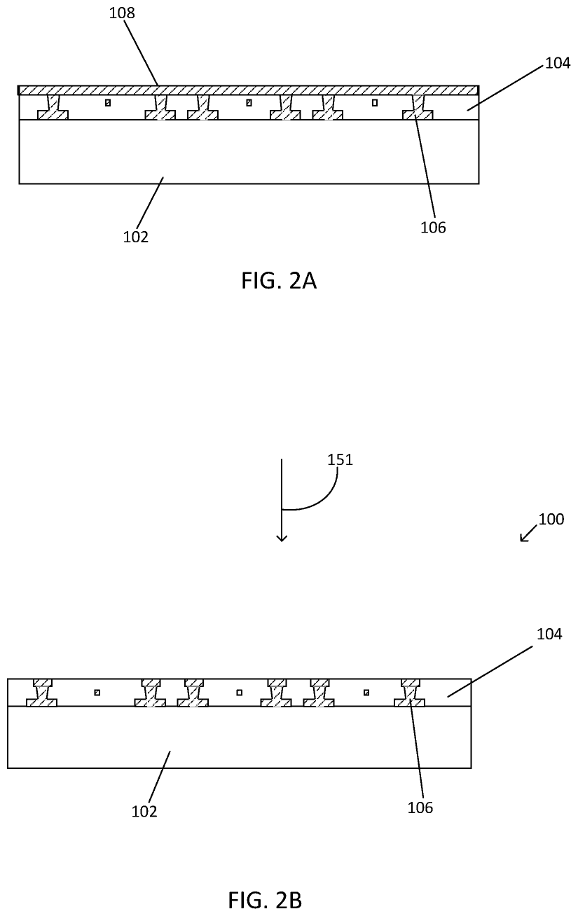

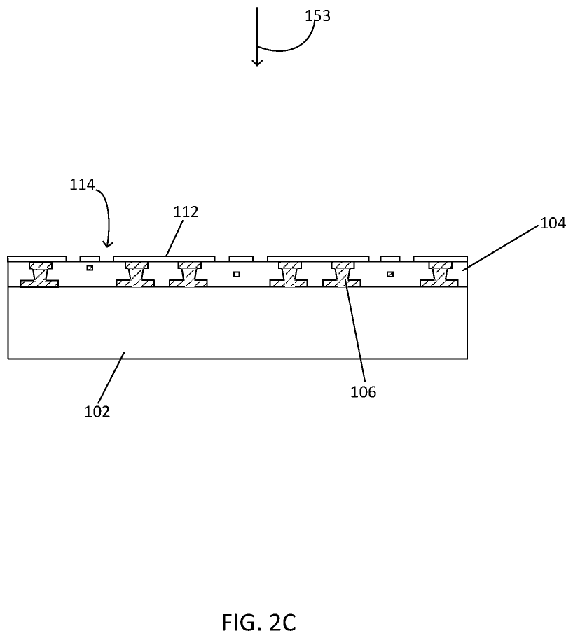

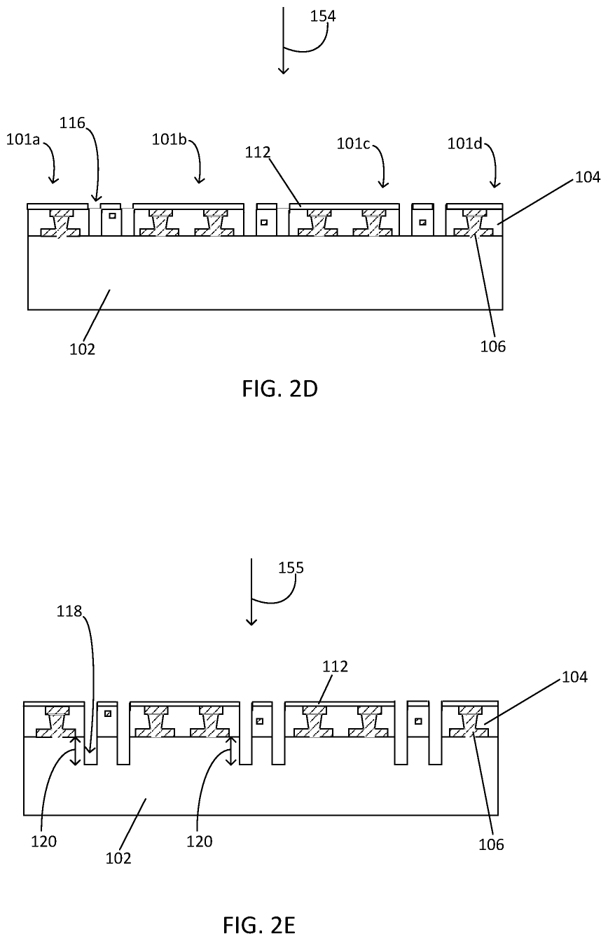

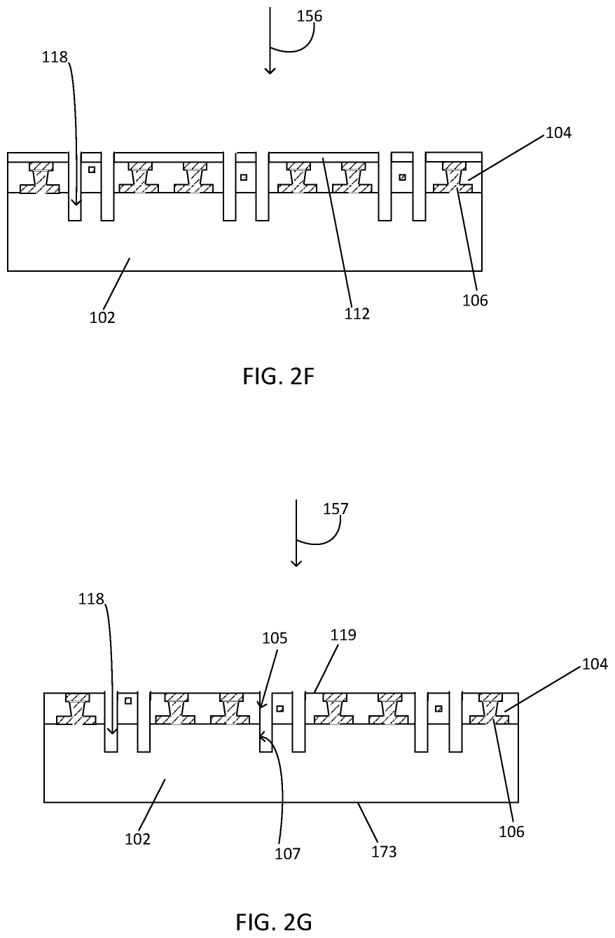

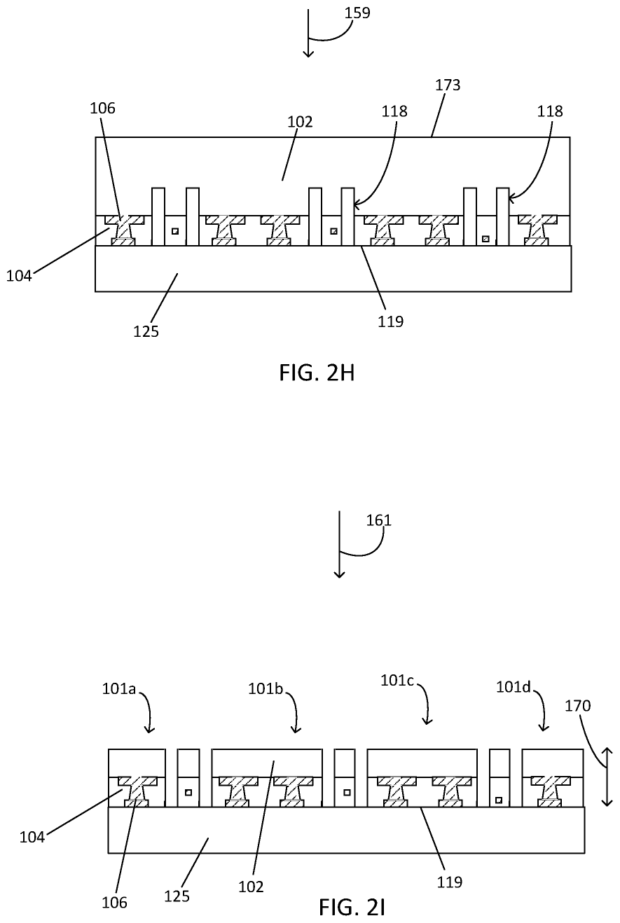

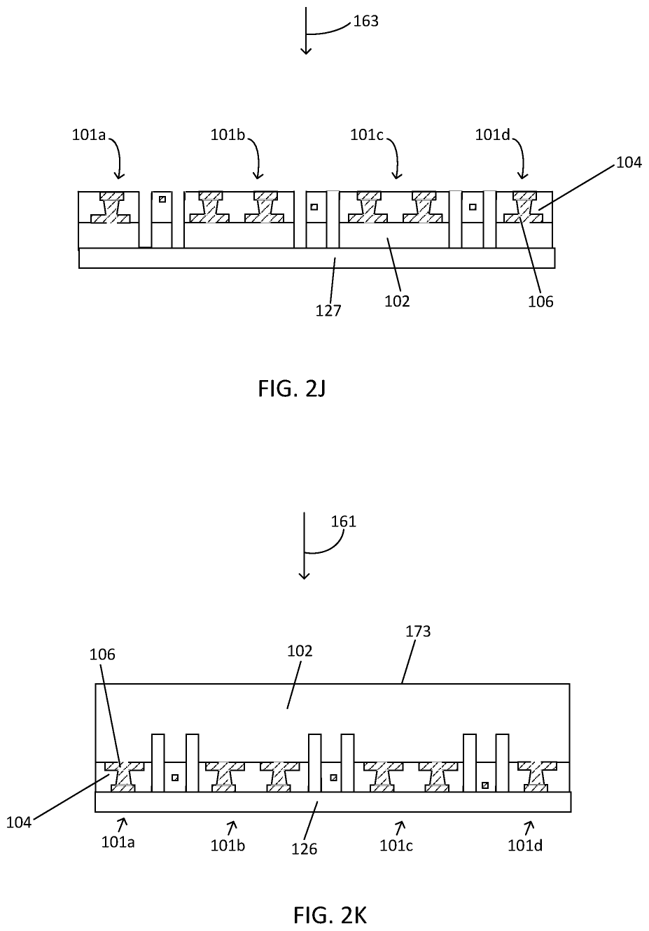

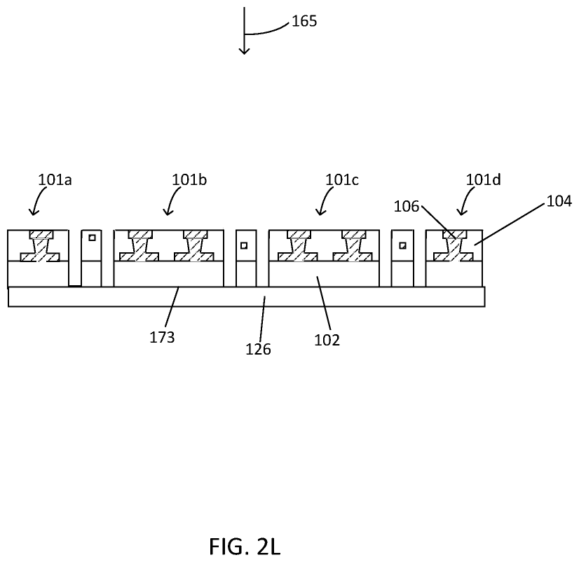

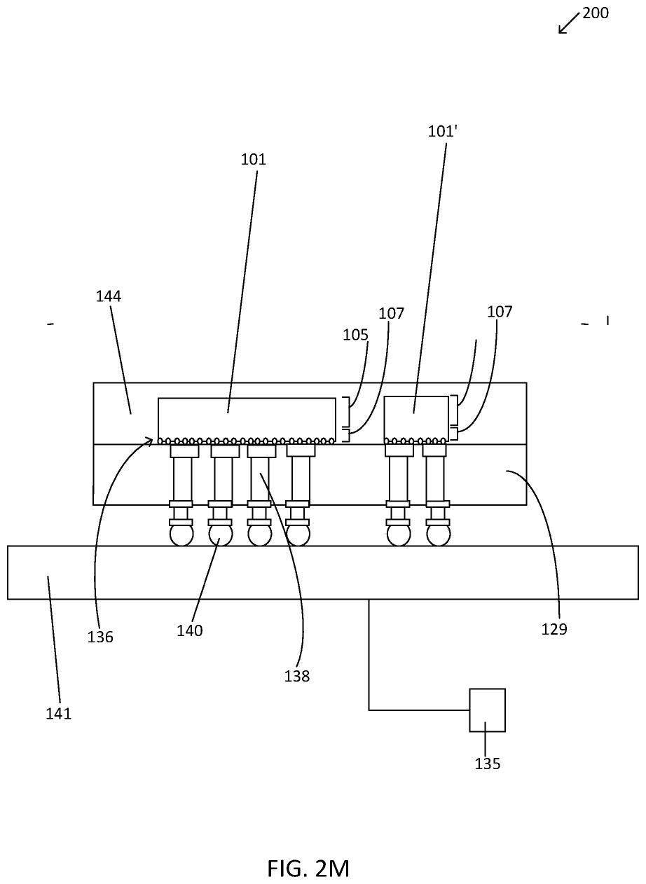

FIGS. 2A-2M illustrate embodiments of forming IC die structures (such as the IC die structures of FIGS. 1A-1B). FIG. 2A depicts a cross-sectional view of a portion of IC die structures according to some embodiments. As shown, metal structures 106 are within a dielectric portion 104. The dielectric portion 104 may comprise any suitable dielectric materials, such as silicon oxide and or silicon dioxide materials, or any other suitable dielectric materials. The metal structures 106 may comprise metal layers within an IC device, and/or may comprise portions of active and/or passive devices within the dielectric material 104. The dielectric portion 104 is on a substrate 102. In an embodiment, the substrate 102 may comprise a wafer, such as a silicon wafer. The dielectric portion 104 may comprise metal layers/structures 106.

Additionally, the dielectric portion 104 may comprise any number of devices, such as active and/or passive devices. For example, the dielectric portion 104 may comprise transistor devices and/or resistor structures within the dielectric portion 104. In an embodiment, the substrate 102 may comprise a bulk silicon portion 102 and may comprise silicon and/or silicon alloys. A conductive layer 108 is on the dielectric portion 104 and is over the metal structures 106. In an embodiment, the conductive layer 108 may comprise copper, copper alloys or any other suitable conductive material. The conductive layer 108 over the metal structures 106 may be grown electrochemically or may be deposited.

In FIG. 2B, a grinding process 151 may be employed to remove the conductive layer 108. In an embodiment, the grinding process 151 may comprise a chemical mechanical polishing (CMP) process. The grinding process 151 may expose metal structures 106, in an embodiment. The metal structures may comprise any suitable conductive metals and their alloys, such as copper, gold, silver, titanium, tungsten and their alloys, for example. The metal structures 106 may comprise portions of devices and/or routing conductive layers within a die/device.

In FIG. 2C, a photoresist material 112 may be formed (utilizing photoresist formation process 153) on the dielectric portion 104 and may further be patterned to expose portions 114 of the underlying dielectric portion 104. The photoresist material 112 may be patterned such that dielectric material between adjacent dies may be subsequently removed by utilizing a photoresist formation and patterning process 153.

In FIG. 2D, a removal process 154 may be employed to remove the exposed portions of the dielectric portion 104 over the substrate 102. In an embodiment, the removal process 154 may comprise a fluorine-based chemistry and may not appreciably etch the substrate 102. In an embodiment, the removal process 154 removes at least partially portions of the exposed dielectric portion 104 in a metal free zone (MFZ) between adjacent dies, such as between adjacent dies 101a, 101b, 101c, 101d, or example. In an embodiment, openings 116 may be formed over the substrate 102, but openings are not formed within the substrate 102. In an embodiment, the photoresist material 112 may comprise about 1 micron or greater in thickness subsequent to the removal process 154.

In FIG. 2E, a removal process 155 may be utilized to remove a portion of the substrate 102 to produce substrate openings 118 in the substrate 102. The photoresist 112 remaining from removal process 154 facilitates the removal of the portion of the substrate 102 during removal process 155. In an embodiment, about 40 microns or greater of the substrate may be removed during removal process 155 (dependent upon the opening size 116/118), which may comprise a front side partial plasma dicing process. Such a partial etch depth of the substrate 102 ensures the structural integrity of the substrate 102 without the need for additional carriers underneath the substrate 102.

In an embodiment, the substrate 102 comprises a bulk silicon material, and the removal process 155 may comprise a Bosch process and may comprise a partial plasma dice (PD) process. In an embodiment, the removal process 155 may comprise a silicon etch, and may comprise a fluorine based etch process, such as a deep reactive ion etch (DRIE). In an embodiment, the substrate openings 118 in the substrate 102 may comprise a depth 120 of about 40 microns or greater. In an embodiment the partial PD process 155 may comprise a cyclic etch process, wherein a first passivation cycle, a second directional etch cycle and a third isotropic etch cycle may be repeated. In an embodiment, the PD process 155 may produce a sidewall profile comprising scalloped regions 109, as depicted in FIG. 1A, for example.

In FIG. 2F, the photoresist material 112 may be removed utilizing a removal process 156 subsequent to the formation of the substrate openings 118. The photoresist material 112 may undergo an ashing process wherein the photoresist material may be removed.

In FIG. 2G, a wet etch process 157 can be employed to remove debris and polymeric photo resist from the previous photoresist removal process, revealing the openings 118 adjacent to the metal structures 106. A sidewall profile 105 of the dielectric portion 104 is continuous with a sidewall profile 107 of the substrate 102 (as depicted in FIG. 1A for example), thus there is no misalignment of the future scribe alley. A surface 119 of the dielectric portion 104 may be coplanar with top portions of the openings 118. A surface 173 of the substrate 102 may be opposite the surface 119 of the dielectric portion 104.

In FIG. 2H, in an embodiment, the surface 119 of the dielectric portion 104 may be flipped and temporarily bonded 159 utilizing bonding process 159 to a carrier 125, which may comprise a glass carrier or silicon carrier in an embodiment.

In FIG. 2I, the surface 121 of the substrate 102 may be undergo a grinding process 161 to reveal openings 118. In an embodiment, the grinding process 161 may comprise a mechanical grind process or a combination of a mechanical grinding and chemical mechanical polishing (CMP) process.

In an embodiment, the grinding process 161 may remove the bulk of the substrate 102 wherein about 30 microns or greater remains. By utilizing the dice before grind (DBG) process presented in the embodiments herein, the surfaces 119 of the singulated dies 101a-d after release from 125 comprise a flat surface which is advantageous for subsequent hybrid bonding to another die. Also, a thickness 170 of the die after the grinding process 161 is performed may be less than about 80 microns in an embodiment or can be optimized according to design needs.

In FIG. 2J, process 163 may be employed to de-bond the dies 101a-d from the carrier 125, where the dies 101a-d are then flipped (such that active dielectric/Cu surface is facing up) and placed on a ring frame 127. In this manner, the dicing before the grinding process (DBG) is utilized to achieve die to wafer singulation.

In FIG. 2M, the dice 101a-d may then be placed on a package substrate 129, in an embodiment.

In another embodiment, the dies 101a-101d may be alternatively placed on a tape 126, such as a backside grind (BG) tape (referring back to FIG. 2K), and the surface 173 of the substrate 102 may be undergo a grinding process 161 to reveal openings 118, as shown in FIG. 2L. In an embodiment, the grinding process 161 may comprise a mechanical grinding process alone or in combination with a CMP process. In an embodiment, the grinding process 161 may remove the bulk of the substrate 102 wherein about 30 microns or greater of the substrate remains. In another embodiment, the surface 173 of the substrate 102 may undergo grinding, the dies 101a-d may be de-bonded from the tape 126, and the dies 101a-d may be flipped and placed on a ring frame 127 in a single step 165.

FIG. 2M depicts a package structure 200, wherein dice 101, 101′ are on a substrate 129, such as a package substrate 129 or are on a base die using hybrid bonding or bump bonds for example. The dice 101, 101′ comprise a die profile 107 as depicted in FIG. 1A, for example. The dice 101, 101′ may be conductively coupled to the package 129 by conductive structures 136. The conductive structures 136 may comprise any conductive element for coupling to an outside die or other device. In an embodiment, the conductive structures 136 may include one or more of silver, tin, or copper, or combinations or alloys thereof. In an embodiment, the conductive structures 136 may be hybrid bonded to a base die/substrate 129.

The dice 101, 101′ may be surrounded by a molding compound 144, or any other suitable gap fill material such as flowable mold compound or deposited material.

Conductive vias 138 and solder balls 140 may couple the dice 101, 101′ to a board 141, such as a printed circuit board, for example. Conductive via structures 138 may comprise copper via structures in an embodiment. In some embodiments the conductive via structures 138 may comprise any suitable conductive material. In an embodiment, the conductive via structures 138 may comprise plated copper via structures 138. A power supply 135, which may comprise any suitable power supply as known in the art, may be coupled to dies 101, 101′ via IC package structure 200, in an embodiment.

Discussion now turns to operations for assembling and/or fabricating the discussed structures.

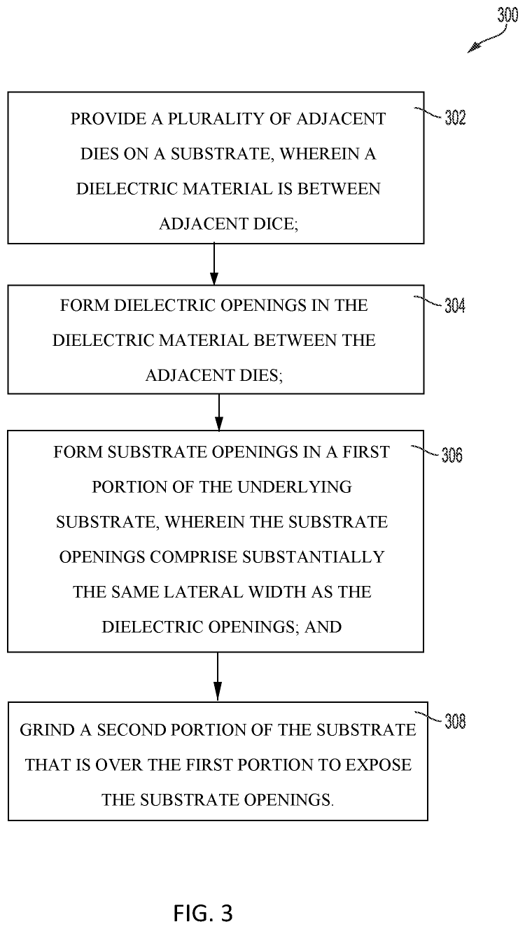

FIG. 3 is a flow chart of a process 300 of fabricating microelectronic IC die structures according to some embodiments. For example, process 300 may be used to fabricate any of the microelectronic IC package structures of FIGS. 2A-2M.

As set forth in block 302, a plurality of adjacent dies on a substrate may be provided, wherein a dielectric material is between adjacent die. The plurality of dies may comprise any suitable die types which are to be subsequently singulated from each other. In an embodiment, the dies may comprise dies that are on a wafer to be singulated. The plurality of dies may come from different wafers in an embodiment. In embodiment, the die may comprise metal layers within a dielectric material which is on a bulk silicon substrate/wafer. In an embodiment, the dielectric material may comprise silicon, oxygen, nitrogen, carbon, or any suitable combinations thereof. In an embodiment, the substrate may comprise a bulk silicon portion of the dies to be singulated. In an embodiment, the die may comprise any type of device or devices within the dielectric material.

As set forth in block 304, dielectric openings are formed in the dielectric material between the adjacent dies. In an embodiment, the openings may be formed using an etch process such as a fluorine containing dry etch chemistry with a plasma processing tool. In an embodiment, a photoresist material may be formed adjacent to metal free zones between adjacent die on the substrate, such that the etch process removes exposed dielectric material between adjacent die. In an embodiment, the openings are formed such that the etch is selective to the substrate. In an embodiment, the dielectric etch is selective to silicon, such that the silicon substrate is not etched by the dielectric etch. In an embodiment, the openings are within the metal free zone between adjacent die.

As set forth in block 306, substrate openings may be formed in a first portion of the underlying substrate, wherein the substrate openings comprise substantially the same lateral width as the dielectric openings. In an embodiment, a substrate opening etch process may be employed to form openings in a portion of the substrate underlying the adjacent dies.

In an embodiment, the substrate openings may be formed through the dielectric openings. In an embodiment, the substrate opening removal process may comprise a directional reactive ion etch, and may comprise a fluorine containing chemistry, such as a silicon fluoride etch chemistry. Because the substrate removal process is performed through the dielectric openings that were previously formed, the substrate openings and the dielectric openings comprise substantially the same slope. In other words, a sidewall profile of the dielectric openings is in vertical alignment with a sidewall profile of the substrate openings. The substrate removal process does not etch though the entire thickness of the substrate but removes greater than about 40 microns of the substrate material as required per the particular application. In an embodiment, a first portion of the substrate is removed and a second portion of the substrate remains unetched.

In an embodiment, the sidewall profiles of the substrate openings between adjacent dies may comprise a plurality of scalloped structures (as depicted in FIG. 1A, for example). The scalloped sidewalls are the result of the cyclic nature of the substrate removal process. For example, the substrate removal process may comprise a plasma dicing process, such as a DRIE Bosch process, wherein the plasma dicing process comprises a cyclic process. In the cyclic process, a first phase comprises a passivation process, a second cycle comprises a directional etch, and a third cycle comprises an isotropic etch. The repetition of the three cycles results in the scalloped sidewall profile as depicted in FIG. 1A, for example.

In an embodiment, individual scallops may comprise a lateral width of between about 0.2 micron to about 5 microns, and the lateral widths of the scallops may decrease as the depth of the etch is increased. The lateral width of the scallops may be optimized by varying the substrate removal etch parameters, depending upon particular design requirements, and may be greater or less than 0.2-5 microns, in an embodiment. In an embodiment, the first portion of the substrate that is removed comprises a depth of about 40 microns or greater. In an embodiment, the substrate removal process may comprise a timed etch.

As set forth in block 308, the second portion of the substrate that is over the first portion undergoes a grinding process to expose the substrate openings. In an embodiment, the first portion is bonded to a carrier, such as a tape, a glass carrier, or a silicon carrier for example, and then the grinding process may be performed to remove the second, unetched portion of the substrate. Top portions of the substrate dielectric openings may be coplanar with the surface of the substrate subsequent to the grinding process. In an embodiment, about 30 microns or greater of the substrate may remain subsequent to the grinding process, depending upon design requirements. In an embodiment, the grinding process may comprise any suitable grinding process, such as a mechanical grinding process alone or optionally in combination with a CMP process, or for example.

In this manner, the dies may be singulated/separated from each other, and may then be placed on a carrier, such as a glass carrier or a tape. The dies may then undergo a pick and place process subsequent to the singulation of the die. The singulated die may then be bonded/coupled to a substrate, such as a package substrate, in subsequent processing operations as is known in the art. In other embodiments, the dies may be hybrid bonded to a wafer or to another die, utilizing a hybrid bonding process as is known in the art, wherein conductive features, on the die such as copper for example, may be hybrid bonded to conductive structures on another die or wafer. For example, conductive features, on a die such as copper for example, may be hybrid bonded to conductive structures on another die or wafer, and wherein dielectric features of the die may bonded to dielectric features on the other die or wafer.

The embodiments described herein enable a frontside PD which reduces the number of processing operations, such as reducing the number of lithographic tools/operations (such as the use of infrared cameras to identify alignment markers on front and back sides of the substrate. Instead, the embodiments herein enable self-aligned scribe lines/alleys. Additionally, the reliance on the accuracy of backside patterning (which is dependent on the resolution and accuracy of IR camera. Thus, improvement in the placement accuracy of the PD scribe lanes is achieved by utilizing the existing patterning from the partial front side PD. Another key advantage of this approach is that the PD tool is not required to fully singulate the entire silicon depth (about 270 microns or greater), for example, and PD defects such as notching are greatly reduced and/or eliminated. Additionally, processing time is greatly improved as the processing tool does not have to etch the entirety of the substrate. Tool availability is increased which results in the number of process tools required for manufacturing to be decreased, thus reducing manufacturing cost.

The partial PD methodology described in the embodiments herein improves the PD tool run rate. Furthermore, the die backside grind operation directly grinds a portion of the top of the die in a single step rather than grinding the entire substrate to about 270 microns and then subsequently grinding further to about 30 microns or more.

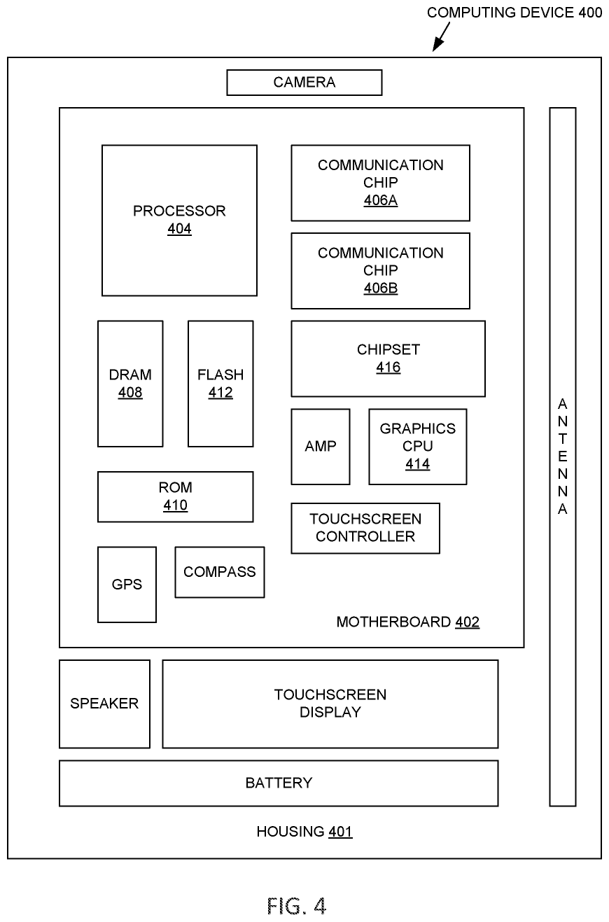

FIG. 4 illustrates an electronic or computing device 400 in accordance with one or more implementations of the present description. The computing device 400 may include a housing 401 having a board 402 disposed therein. The computing device 400 may include a number of integrated circuit components, including but not limited to a processor 404, at least one communication chip 406A, 406B, volatile memory 408 (e.g., DRAM), non-volatile memory 410 (e.g., ROM), flash memory 412, a graphics processor or CPU 414, a digital signal processor (not shown), a crypto processor (not shown), a chipset 416, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 402. In some implementations, at least one of the integrated circuit components may be a part of the processor 404.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include a die having a dielectric portion and a bulk silicon portion. A dielectric die edge sidewall and a bulk silicon die edge sidewall have sidewall profiles that are substantially continuous with each other. The bulk silicon die edge sidewall comprises a plurality of scalloped regions along its vertical distance. An interface region between the dielectric die edge sidewall and the bulk silicon die edge sidewall comprises a substantially vertical interface sidewall and is free of a concave notch in the bulk silicon die edge sidewall.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-4. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, wherein a first example is an apparatus, comprising a die, the die having a dielectric portion comprising a dielectric die edge sidewall having a sidewall profile comprising a substantially continuous sidewall slope. A bulk silicon portion is on the dielectric portion. The bulk silicon portion comprises a bulk silicon die edge sidewall in substantial alignment with the dielectric die edge sidewall. The bulk silicon die edge sidewall has a sidewall profile comprising a plurality of scalloped regions along a vertical distance thereof.

In second examples, the first example further comprises wherein the plurality of scalloped regions comprise a plurality of vertically adjacent concave notches within the bulk silicon die edge sidewall.

In third examples, the second example further comprises wherein individual vertically adjacent concave notches of the plurality of vertically adjacent concave notches comprise a lateral width of between 0.2 micron to 5 microns.

In fourth examples, the second example further comprises wherein an interface region between the dielectric die edge sidewall and the bulk silicon die edge sidewall comprises a substantially vertical interface sidewall and is free of a concave notch in the interface region.

In fifth examples, example 4 further comprises wherein individual vertically adjacent concave notches of the plurality of vertically adjacent concave notches that are closer to the interface region comprise a greater lateral width than a lateral width of individual vertically adjacent concave notches of the plurality of vertically adjacent concave notches that are farther from the interface region.

In sixth examples, for any of examples 1-5 wherein one or more devices are adjacent to the dielectric die edge sidewall and over the bulk silicon portion.

In seventh examples, the sixth example further includes wherein the one or more devices comprise a transistor.

In eighth examples, for any of the examples 1-7 wherein the dielectric portion comprises at least one of oxygen, nitrogen, silicon nitride, or a silicon oxide material.

In ninth examples, for any of the examples 1-8 wherein the dielectric die edge sidewall is free of metal.

In tenth examples, for any of examples 1-9 wherein the dielectric die edge sidewall is free of scalloped regions.

In eleventh examples, for any of examples 1-10 wherein the die is on a package substrate.

The twelfth example is a system comprising a substrate, a die on the substrate, the die comprising a dielectric portion comprising a dielectric die edge sidewall between 0 degrees to 20 degrees of a vertical profile, and a bulk silicon portion on the dielectric portion. The bulk silicon die edge sidewall comprises four concave regions along a vertical distance of the bulk silicon die edge sidewall, and wherein a lateral offset between the dielectric die edge sidewall and the bulk silicon sidewall is less than 2 percent of a vertical profile.

In thirteenth examples, example twelve further comprises wherein an interface region between the dielectric die edge sidewall and the bulk silicon die edge sidewall comprises an interface sidewall that is free of the concave regions.

In fourteen examples, for any of examples 12-13 wherein individual ones of the plurality of concave regions comprise a lateral width of between about 0.2 micron to about 5 microns.

In fifteenth examples 14 further comprises wherein the dielectric portion comprises one or more transistors, wherein the one or more transistors are over the bulk silicon portion and are adjacent to the plurality of concave regions.

In sixteenth examples, for any of examples 12-15 wherein a power supply is coupled to the die.

The seventeenth example is a method, comprising providing a plurality of adjacent die on a substrate, wherein a dielectric material is between adjacent die; forming dielectric openings comprising a lateral width in the dielectric material between the adjacent die; forming substrate openings in a first portion of the substrate, wherein the substrate openings comprise the lateral width of the dielectric openings; and grinding a second portion of the substrate that is over the first portion to expose the substrate openings.

In eighteenth examples, example seventeen further includes wherein forming the substrate openings comprises etching the first portion of a silicon substrate with a silicon fluoride chemistry to a partial depth of the silicon substrate.

In nineteenth examples, example eighteen further includes wherein grinding the second portion comprises grinding a remaining portion of the silicon substrate.

In twentieth examples for any of examples 17-19 wherein forming the substrate openings comprises plasma dicing the substrate.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a die comprising:
a dielectric portion comprising a dielectric die edge sidewall having a sidewall profile comprising a substantially continuous sidewall slope; and
a bulk silicon portion on the dielectric portion, the bulk silicon portion comprising a bulk silicon die edge sidewall in substantial alignment with the dielectric die edge sidewall, the bulk silicon die edge sidewall having a sidewall profile comprising a plurality of scalloped regions along a vertical distance thereof.

2. The apparatus of claim 1, wherein the plurality of scalloped regions comprise a plurality of vertically adjacent concave notches within the bulk silicon die edge sidewall.

3. The apparatus of claim 2, wherein individual vertically adjacent concave notches of the plurality of vertically adjacent concave notches comprise a lateral width of between 0.2 microns to 5 microns.

4. The apparatus of claim 2, wherein an interface region between the dielectric die edge sidewall and the bulk silicon die edge sidewall comprises a substantially vertical interface sidewall and is free of a concave notch in the interface region.

5. The apparatus of claim 4, wherein individual ones of the plurality of vertically adjacent concave notches that are closer to the interface region comprise a greater lateral width than a lateral width of individual ones of the plurality of vertically adjacent concave notches that are farther from the interface region.

6. The apparatus of claim 1, wherein one or more devices are adjacent to the dielectric die edge sidewall and over the bulk silicon portion.

7. The apparatus of claim 6, wherein the one or more devices comprise a transistor.

8. The apparatus of claim 1, wherein the dielectric portion comprises at least one of oxygen, nitrogen, silicon nitride, or a silicon oxide material.

9. The apparatus of claim 1, wherein the dielectric die edge sidewall is free of metal.

10. The apparatus of claim 1, wherein the dielectric die edge sidewall is free of scalloped regions.

11. The apparatus of claim 1, wherein the die is on a package substrate.

12. A system, comprising:
a substrate;
a die on the substrate, the die comprising:
a dielectric portion comprising a dielectric die edge sidewall between 0 degrees to 20 degrees of a vertical profile; and
a bulk silicon portion on the dielectric portion, wherein a bulk silicon die edge sidewall comprises four concave regions along a vertical distance of the bulk silicon die edge sidewall, and wherein a lateral offset between the dielectric die edge sidewall and the bulk silicon sidewall is less than 2 percent of a vertical profile.

13. The system of claim 12, wherein an interface region between the dielectric die edge sidewall and the bulk silicon sidewall comprises an interface sidewall that is free of the concave regions.

14. The system of claim 12, wherein individual ones of the four concave regions comprise a lateral width of between about 0.2 micron to about 5 microns.

15. The system of claim 14, wherein the dielectric portion comprises one or more transistors, wherein the one or more transistors are over the bulk silicon portion and are adjacent to the plurality of concave regions.

16. The system of claim 12, wherein a power supply is coupled to the die.

17. A method, comprising:
providing a plurality of adjacent die on a substrate, wherein a dielectric material is between adjacent die;
forming dielectric openings comprising a lateral width in the dielectric material between the adjacent die;
forming substrate openings in a first portion of the substrate, wherein the substrate openings comprise the lateral width of the dielectric openings; and
grinding a second portion of the substrate that is over the first portion to expose the substrate openings.

18. The method of claim 17, wherein forming the substrate openings comprises etching the first portion of a silicon substrate with a silicon fluoride chemistry to a partial depth of the silicon substrate.

19. The method of claim 18, wherein grinding the second portion comprises grinding a remaining portion of the silicon substrate.

20. The method of claim 17, wherein forming the substrate openings comprises plasma dicing the substrate.
